(19) United States
(12) Patent Application Publication
(10) Pub. No.: US 2012/0192918 A1
(43) Pub. Date: Aug. 2, 2012

(54) SOLAR CELL MODULES COMPRISING CONDUCTIVE RIBBONS WITH DIFFUSE REFLECTIVE COVERS

(75) Inventors: Zuocheng Zhou, Shanghai (CN); Chao Yan, Shanghai (CN); Philip L. Boydell, Challex (FR)

(73) Assignee: E.I. DU PONT DE NEMOURS AND COMPANY, Wilmington, DE (US)

(21) Appl. No.: 13/192,764

(22) Filed: Jul. 28, 2011

(30) Foreign Application Priority Data
Jul. 30, 2010 (CN) 201010251354.5

(51) Int. Cl. H01L 31/052

(52) U.S. Cl. 136/246

(57) ABSTRACT

A solar cell module is provided that has a plurality of electrically interconnected solar cells, wherein each solar cell comprises a photoelectric conversion body, one or more conductive ribbons, and one or more reflective strips. The electrically conductive ribbons are disposed over a portion of the front surface of the photoelectric conversion body. The reflective strips are disposed over the electrically conductive ribbons. The reflective strips have an average total reflectance of at least about 20% and a ratio of average diffuse reflectance to average total reflectance of at least about 0.2.

### FIELD OF DISCLOSURE

The disclosure is related to solar cell modules, and more particularly to solar cell modules comprising solar cells with conductive ribbons that have diffuse reflective covers for increasing the power output.

### BACKGROUND

Solar cells, also referred to as photovoltaic cells, are well known devices for converting solar radiation to electrical energy. A conventional solar cell 10, as shown in FIGS. 1 and 2, includes a photoelectric conversion body 11 sandwiched between two electrodes. The photoelectric conversion body is typically a monocrystalline or polycrystalline silicone wafer. The first or front electrode is formed on the front or top light receiving surface of each photoelectric conversion body 11. The front electrode includes a plurality of substantially parallel conductive fingers 12 and two or more conductive bus bars 13 running generally perpendicular to the conductive fingers 12. The bus bars 13 electrically connect the conductive fingers 12. The conductive fingers 12 and the conductive bus bars 13 are typically formed from a conductive paste, such as a silver paste, that is fired on the surface of the photoelectric conversion body. A second or back electrode (not shown) is formed on the back or bottom surface of each photoelectric conversion body. The back electrode is formed by firing a conductive paste, such as aluminum paste, on the back side of the photoelectric conversion body. The solar cell 10 further comprises two or more conductive ribbons 14 (such as copper ribbons or wires) aligned with and soldered over the two or more conductive bus bars 13. The conductive ribbons 14 serve to efficiently carry out the electric current from the bus bars of the solar cell. In addition, when multiple solar cells are included in a solar cell module, each of the conductive ribbons 14 may have an end 14b that extends beyond the perimeter of the solar cell 10 so as to be bonded to the back electrode of an adjacent solar cell 10 and provide electrical connection between adjacent solar cells.

Wider conductive ribbons are typically more conductive than narrower ribbons for a given height. Accordingly wider ribbons should deliver improved current flow from the solar cells. However, wider conductive ribbons attached over the front side of the photoelectric conversion body cover a greater area of the front surface of the solar cell than that covered by narrower ribbons. Such greater coverage necessarily reduces the amount of solar radiation striking the front surface of the solar cell, consequently off-setting some or all of the efficiency gains from the increased conductivity of wider conductive ribbons.

There is a need for solar cell conductive ribbons that cause less of a reduction of solar radiation making it to the photoelectric conversion body of the solar cells so as to provide solar modules with higher power output.

### SUMMARY

Disclosed herein is a solar cell module with a plurality of solar cells each comprising a photoelectric conversion body having a light receiving front surface; one or more electrically conductive ribbons disposed over a portion of the front surface of the photoelectric conversion body; and one or more reflective strips disposed over the second side of said one or more electrically conductive ribbons. Each of the reflective strips has an average total reflectance of at least about 20% and a ratio of average diffuse reflectance to average total reflectance of at least about 0.2, where the average total reflectance and the average diffuse reflectance are measured at wavelengths from 300 to 1500 nm.

In a preferred embodiment, each of the plurality of solar cells comprises two of the electrically conductive ribbons and a reflective strip over each of the electrically conductive ribbons.

In a preferred embodiment, each of the plurality of solar cells further comprises a front electrode on the light receiving front surface of the photoelectric conversion body and a back electrode printed over a back surface of the photoelectric conversion body that is opposite the front surface. The front electrode comprises a plurality of substantially parallel electrically conductive fingers and one or more electrically conductive bus bars substantially perpendicular to and connected to the electrically conductive fingers, wherein each of the electrically conductive ribbons is aligned with and bonded to one of the electrically conductive bus bars. Each of the electrically conductive ribbons may be soldered to one of the electrically conductive bus bars.

In a preferred embodiment, each of the reflective strips has an average total reflectance of at least about 50%, and a ratio of average diffuse reflectance to average total reflectance of at least about 0.5, where the average total reflectance and the average diffuse reflectance are measured at wavelengths from 300 to 1500 nm.

In another preferred embodiment, each of the reflective strips comprises a polymer composition comprising at least one polymeric material selected from the group consisting of fluoropolymers, polyesters, polyolefins, ethylene vinyl acetates, polycarbonates, polyurethanes, silicones, epoxy resins, and combinations of two or more thereof. The polymer composition in each of the reflective strips may further comprises at least one additive selected from the group consisting of titanium dioxide, silica, aluminum oxide, zinc oxide, magnesium oxide, calcium carbonate, aluminum silicate, calcium sulfate, silicon carbide, barium carbonate, barium sulfate, and combinations of two or more thereof. For example, the polymer composition in each of the reflective strips may comprises a fluoropolymer and titanium oxide particles.

In one preferred embodiment, the polymer composition in each of the reflective strips comprises polyvinyl fluoride and about 10-30 wt % of titanium oxide particles, based on the total weight of the polymer composition. The reflective strip may comprise a reflective coating on a side facing away from the conductive ribbon over which the reflective strip is disposed. The reflective coating may comprises a material selected from the group consisting of titanium dioxide, silica, aluminum, silver, and a combination of two or more thereof.

In a preferred embodiment, each of the electrically conductive ribbons has a width that is about 70-100% of that of the conductive bus bar the electrically conductive ribbon is bonded over. Each of the electrically conductive ribbons may have (i) a main portion that covers at least about 95% of the entire length of the conductive bus bar it is bonded over and (ii) an extended portion that extends beyond the conductive bus bar it is bonded over and that is bonded to the back electrode of an adjacent solar cell of the plurality of solar cells of the solar cell module. Each of the reflective strips may have a width that is at least 80% of the width of the conductive ribbon it is disposed over, and each of the reflective strips may cover at least 95% of the portion of each conductive ribbon that is aligned with and bonded to a bus bar.

In a preferred embodiment, the plurality of solar cells are electrically connected to each other and are encapsulated between a front encapsulant sheet and a back encapsulant sheet. The front encapsulant sheet and the back encapsulant sheet may independently comprises a polymeric material selected from the group consisting of ethylene vinyl acetates, ionomers, poly(vinyl butyral), polyurethanes, polyvinylchlorides, polyethylenes, polyolefins, ethylene acrylate ester copolymers, acid copolymers, silicones, epoxy resins, and combinations of two or more thereof. These encapsulated solar cells may be further sandwiched between a transparent frontsheet and a backsheet. The transparent frontsheet is preferably selected from the group consisting of glass sheets and plastic sheets and the backsheet is selected from the group consisting of glass sheets, plastic sheets, metal sheets, and ceramic plates. The plastic sheets may comprise material selected from the group consisting of polycarbonates, acrylics, polyacrylates, cyclic polyolefins, ethylene norbornene polymers, polystyrenes, polyamides, polyesters, fluoropolymers, and combinations of two or more thereof.

### DRAWINGS

The detailed description will refer to the following drawings which are not drawn to scale.

FIG. 1 is a top schematic view of adjacent solar cells according to the prior art.

FIG. 2 is a schematic cross sectional view of adjacent solar cells taken along the line II-II of FIG. 1.

FIG. 3 is a schematic cross sectional view of adjacent solar cells as disclosed herein.

FIG. 4 is a schematic cross sectional view of a solar cell as disclosed herein taken in a direction substantial perpendicular to the view shown in FIG. 3.

FIG. 5 is a schematic cross sectional view of the solar cell module disclosed herein.

### DETAILED DESCRIPTION

Disclosed herein is a solar cell module comprising a plurality of electrically interconnected solar cells, wherein each solar cell comprises a photoelectric conversion body, one or more conductive ribbons, and one or more reflective strips. The one or more electrically conductive ribbons are disposed over a portion of the front surface of said photoelectric conversion body. The electrically conductive ribbons have opposite first and second sides, where the first side of the electrically conductive ribbons face the photoelectric conversion body and are electrically connected to the photoelectric conversion body. The one or more reflective strips are disposed over the second side of the one or more electrically conductive ribbons. The reflective strips have an average total reflectance of at least about 20% and a ratio of average diffuse reflectance to average total reflectance of at least about 0.2.

The reflectance of an object consists of specular reflectance due to coherent scattering of light on the surface, e.g., mirror reflection, and diffuse reflectance that stems from backward scattering of light. As used herein, the “percent total reflectance” refers to the ratio of reflected light (including specular reflection and diffuse reflection) from an object relative to the incident light that impinges on the object at certain wavelength. As used herein, the “percent diffuse reflectance” refers to the ratio of reflected light generated by diffuse reflection from an object relative to the incident light that impinges on the object at certain wavelength. As used herein, the average total reflectance and the average diffuse reflectance are measured at wavelengths from 300 to 1500 nm. The “average total reflectance” is an average of the percent total reflectance of an object determined at each wavelength from 300 to 1500 nm in 5 nm intervals. The “average diffuse reflectance” is an average of the percent diffuse reflectance of an object determined at each wavelength from 300 to 1500 nm in 5 nm intervals. Finally, the ratio of average diffuse reflectance to average total reflectance is the ratio of the average percent diffuse reflectance to the average percent total reflectance.

When in use, a solar cell module is positioned such that the front or top surface of the solar cell receives the solar radiation while the back or bottom surface of the solar cell faces away from the solar radiation. Accordingly, each component in the solar cell module has a front (or top) surface facing toward the solar radiation and a back (or bottom) surface facing away from the solar radiation.

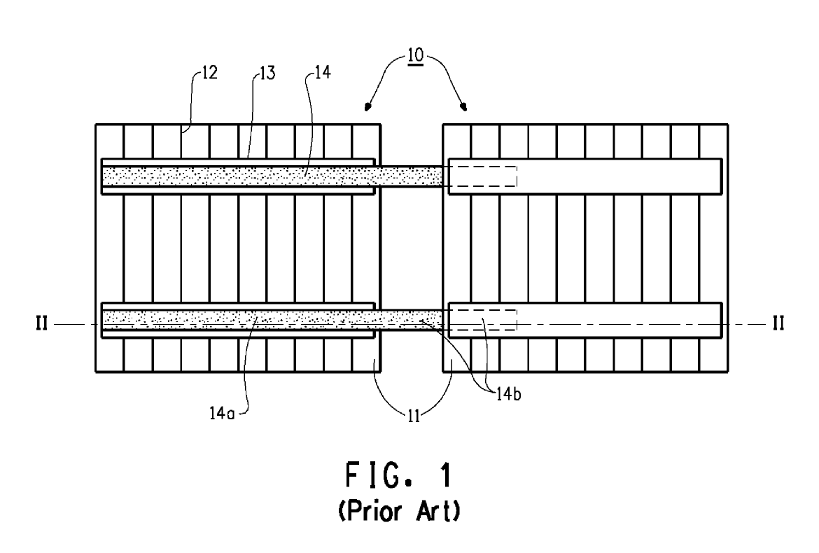

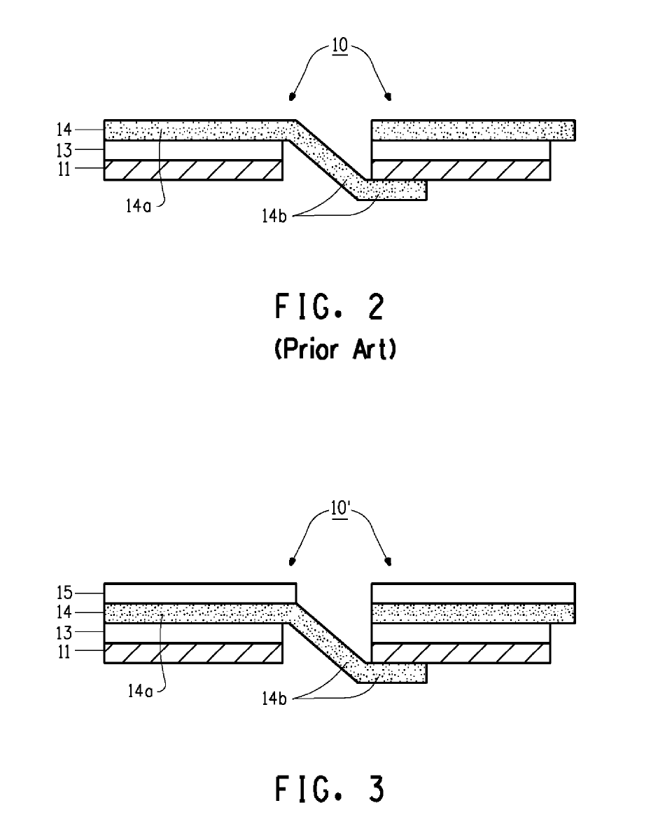

As illustrated in FIGS. 1 and 2, conventional solar cells 10 are each formed of a photoelectric conversion body 11 with electrodes formed on both main surfaces of each solar cell. The photoelectric conversion body 11 of each solar cell may be made of any suitable photoelectric conversion materials, such as monocrystalline or polycrystalline silicon wafers. A front electrode is formed on the front surface of the photoelectric conversion body and a back electrode is formed on the back surface of the photoelectric conversion body. The front electrodes are typically formed of a conductive paste, such as silver paste or other conductive metal paste, which is applied on the front surface of the photoelectric conversion body and then fired. The metal paste is applied by any suitable deposition process, such as screen printing or ink-jet printing. Typically, the front electrode comprises a plurality of substantially parallel electrically conductive fingers 12 and one or more electrically conductive bus bars 13 that are formed substantially perpendicular to the conductive fingers and that electrically connect to the conductive fingers. Each of the conductive fingers 12 typically has a width in the range of about 30 μm to about 200 μm, while each of the conductive bus bars 13 typically has a width in the range of about 0.5 to about 3 mm. Back electrodes (not shown in the figures) may be formed by printing metal paste over the entire back surface of the photoelectric conversion body. Suitable metals for forming the back electrodes include, but are not limited to, aluminum, copper, silver, gold, nickel, cadmium, and alloys and combinations thereof.

A conventional solar cell further comprises one or more conductive ribbons 14 aligned with and bonded on the electrically conductive bus bars 13. The conductive ribbons 14 are typically soldered to the electrically conductive bus bars 13. The conductive ribbons are included to efficiently collect the electric current generated by the solar cell and to transmit the current from the solar cell to an adjacent cell or to an external lead. The conductive ribbons 14 are formed of any highly conductive material, such as copper, silver, aluminum, gold, nickel, cadmium, and alloys thereof. The electrically conductive ribbons 14 are typically made in the form of metal strips, or more preferably, metal strips coated with soldering material (such as tin coatings). The ribbons 14 are aligned with and adhered over the conductive bus bars 13 by any suitable bonding process, such as by soldering. The electrically conductive ribbons 14 may alternatively be bonded to the conductive bus bars 13 using a conductive adhesive.

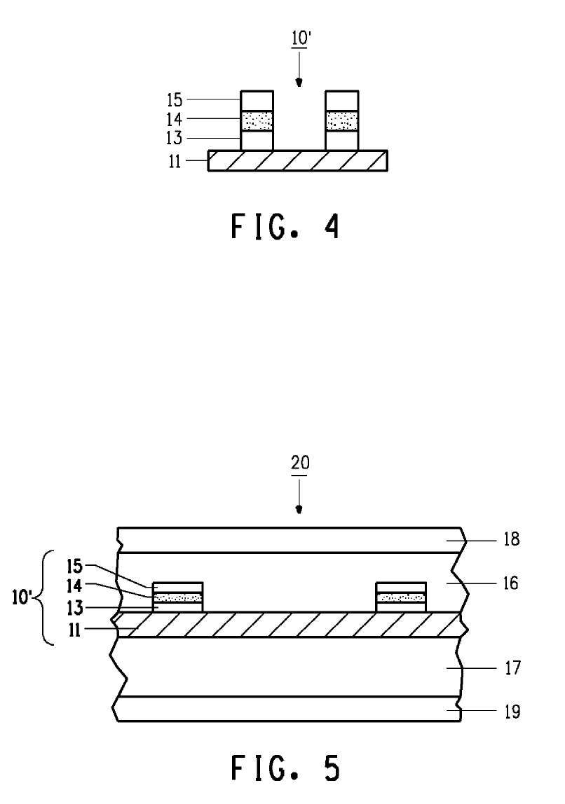

FIG. 3 shows a cross sectional view of adjacent solar cells 10′ of a solar module as disclosed herein. The solar cells 10′ are similar to the solar cells shown in FIGS. 1 and 2, but the solar cells 10′ further comprises one or more reflective strips 15 positioned over a front surface of each of the conductive ribbons 14. FIG. 3 shows a cross sectional view of the disclosed solar cells taken in the same direction as the cross sectional view of the conventional solar cells of FIG. 2. FIG. 4 shows a cross section view of the disclosed solar cells taken in a direction that is substantially perpendicular to the direction of the cross sectional view of FIG. 3. The disclosed solar cells 10′ are incorporated into a solar cell module as shown in the partial cross section in FIG. 5. The solar cell module 20 includes a plurality of electrically interconnected solar cells 10′, a portion of one of which is shown in FIG. 5. The solar cell 10′ is encapsulated by a transparent front encapsulant 16 and a back encapsulant 17, and is further sandwiched between a transparent protective frontsheet 18 and a protective backsheet 19.

In the solar cells 10′ of the disclosed solar cell module, each of the reflective strips 15 have an average total reflectance of at least about 20%, and preferably at least about 35%, and more preferably at least about 50%, and yet more preferably at least about 65%. In the solar cells of the disclosed solar cell module, each of the reflective strips 15 have a ratio of average diffuse reflectance to average total reflectance of at least about 0.2, and preferably at least about 0.5, and more preferably at least about 0.7. The average total reflectance and the average diffuse reflectance are measured at wavelengths from 300 to 1500 nm by the method described above. The light that is reflected by the reflective strips 15 reflects into the encapsulant layer 16 and the front sheet 18. A portion of this reflectance is reflected by the encapsulant layer and/or the front sheet back to the photoelectric conversion body 11 which serves to increase the conversion efficiency of the solar cells and the solar module.

Each of the conductive ribbons 14 may have a width that is the same as or less than that of the conductive bus bars 13. In one embodiment, the width of the conductive ribbons 14 is about 50% to about 100%, or preferably about 70% to about 100%, or more preferably about 90% to about 100% of that of the conductive bus bars 13 to which the conductive ribbons are bonded. In addition, each conductive ribbon 14 may comprise a main portion 14a and an extended portion 14b as shown in FIG. 3. The main portion 14a is the portion of the electrically conductive ribbon 14 that is positioned directly over the conductive bus bar 13 to which the conductive ribbon is bonded. The extended portion 14b is the portion of the conductive ribbon 14 that extends beyond the conductive bus bar 13 to which the conductive ribbon is bonded. The extended portion 14b may contact with the back electrode of an adjacent solar cell 10′ as shown in FIG. 3. The conductive ribbon 14 may have a length such that its main portion covers at least 95% or the entire length of the conductive bus bar 13 to which it is bonded.

The reflective strips 15 used in the disclosed embodiments may have a thickness in the range of about 1 to about 200 μm, or preferably about 10 to about 100 μm, or more preferably about 20 to about 50 μm. The width of the reflective strips 15 may be designed depending on the width of the conductive ribbons 14 over which the reflective strips 15 are positioned. In general, the reflective strips 15 should have a width such that when the reflective strips 15 are positioned over the conductive ribbons 14 within the solar cell module, they cover from 80% to 100% or close to about 100% of the width of the conductive ribbons 14 while covering about 0% or close to about 0% of the front surface area of the photoelectric conversion body 11 that are not covered by the conductive ribbons 14. In one embodiment, the reflective strips 15 have a width that is about 80% to about 100%, or preferably about 90% to about 100%, or more preferably about 95% to about 100% of the width of the conductive ribbons 14. Each of the reflective strips 15 may have a length such that about at least 95% of the top or front surface of the main portion 14a of the conductive ribbon (the portion of the conductive ribbon 14 that is aligned with and bonded to the bus bar 13) is covered by the reflective strip 15. As used herein, the term “close to about 0%” refers to a value of less that about 5%, while the term “close to about 100%” refers to a value of more than about 95%.

The reflective strips 15 may be in the form of polymeric sheets with inorganic fillers. The reflective strips are typically formed from larger polymer sheets that are cut into strips and applied on the conductive ribbons 14. Alternatively, the reflective strips may be formed as coated strips directly on the conductive ribbons 14. The reflective strips may comprise any suitable polymeric materials, which include, but are not limited to, fluoropolymers (such as fluorinated ethylene propylene (FEP), poly(ethylene-co-tetrafluoroethylene) (ETFE), tetrafluroethylene/hexafluropropylene/vinylidene fluoride termpolymer (THV), polyvinylidene fluoride (PVDF), ethylene/chlorotrifluoroethylene copolymer (ECTFE), or polychlorotrifluoroethylene (PCTFE)); polyesters (such as polyethylene terephthalate (PET), polytrimethlene terephthalate (PTT), polyethylene naphthalate (PEN), or poly(methyl methacrylate) (PMMA)); polyolefins (such as polyethylene or polypropylene); ethylene vinyl acetates (EVA); polycarbonates; polyurethanes; silicone; and combinations of two or more thereof. Suitable inorganic fillers incorporated in the reflective strips include, but are not limited to, titanium dioxide, silica, aluminum oxide, zinc oxide, magnesium oxide, calcium carbonate, aluminum silicate, calcium sulfate, silicon carbide, barium carbonate, barium sulfate, and combinations of two or more thereof. In another embodiment, the reflective strips may be in the form of polymeric sheets with reflective coatings. The reflective coatings may be formed of inorganic reflective coating materials (such as titanium dioxide or silica) or metals (such as aluminum or silver). In one embodiment, the reflective strips 15 may comprise a polyvinyl fluoride and about 10-30 wt % of titanium oxide particles, based on the total weight of the reflective strip composition. In a further embodiment, the following commercially available polymeric materials may be used herein in forming the reflective strips 15: Tedlar® PV2001 PVF films, Tedlar® PV2111 PVF films, Tyvek® HDPE films, and Surlyn®1702 ionomer resins, which are all available from E.I. du Pont de Nemours and Company, U.S.A. (hereafter “DuPont”) and Tetoron® UX150 films, which is available from DuPont Teijin Films, U.S.A.

The reflective strips 15 may be applied over the conductive ribbons 14 by any suitable means. In one embodiment, the reflective strips 15 may be first formed into a strip and then bonded over the conductive ribbons 14 using adhesives. Suitable adhesives include temperature sensitive and pressure sensitive adhesives. Preferably, the adhesives used are pressure sensitive adhesives. Exemplary adhesives include, but are not limited to, polyvinyl acetate (e.g., Bynel®1123 adhesive resins from DuPont), polyvinyl alcohol (e.g., Elvanol® polyvinyl alcohol from DuPont), acrylic adhesive (e.g., Nucrel® 0403 acid copolymer resins from DuPont), polyurethane (e.g., Adcote™ 331 adhesives from Dow Chemical, U.S.A.), cyanoacrylate (e.g., 3M™ Plastic Bonding Adhesive from 3M, U.S.A.), epoxy (e.g., 3M™ Fastbond™ 4224-NF, from 3M), Silicone adhesive (e.g., Dow Corning® 2013 adhesives from Dow Corning, U.S.A.) and the like. In another embodiment, the reflective strips 15 may be applied over the conductive ribbons 14 by first obtaining a solution containing the appropriate polymeric material and the optional additives, spray coating the solution over the conductive ribbons 14, and drying the coating. It is preferred that the spray coating process be conducted after the conductive ribbons 14 have been bonded (e.g., soldered) over the conductive bus bars 13.

Now referring to FIG. 5, within the solar cell module 20 disclosed herein, the one or a plurality of electrically interconnected solar cells 10′ may be encapsulated by a transparent front encapsulant 16 and a back encapsulant 17, which may be further sandwiched between a transparent protective frontsheet 18 and a protective backsheet 19.

The encapsulant layers 16 and 17 of solar cell modules 20 are designed to encapsulate and protect the fragile solar cells against physical or environmental damage, such as air or moisture related degradation. The optical properties of the front encapsulant 16 must be transparent so that solar radiation can be effectively transmitted to the solar cells. Widely used encapsulant materials include complex, multi-component compositions based on ethylene vinyl acetate (EVA), ionomer, poly(vinyl butyral) (PVB), polyurethane (PU), polyvinylchloride (PVC), polyethylenes, polyolefin block elastomers, ethylene acrylate ester copolymers (such as poly(ethylene-co-methyl acrylate) and poly(ethylene-co-butyl acrylate)), acid copolymers, silicones, epoxy resins, and the like.

The frontsheet 18 and backsheet 19 are designed for providing protection and support of the solar cell modules. In general, the frontsheets 18 and backsheets 19 used in the solar cell modules 20 may be derived from any suitable sheets or films. Suitable sheets used herein may be glass sheets; plastic sheets (such as those comprising polycarbonate, acrylics, polyacrylate, cyclic polyolefins, ethylene norbornene polymers, polystyrene, polyamides, polyesters, fluoropolymers, or combinations thereof); metal sheets (such as those comprising aluminum, steel, galvanized steel); or ceramic plates. Again, in order to allow solar radiation reach the solar cells, only transparent materials are used in forming the frontsheets 18.

Any suitable lamination process may be used to produce the solar cell modules disclosed herein. In one embodiment, the process includes: (a) providing a plurality of solar cells, wherein each of the solar cells has a photoelectric conversion body with a front electrode comprising a plurality of parallel conductive fingers and at least one conductive bus bar printed over a front surface of the photoelectric conversion body and a back electrode printed over a back surface of the photoelectric conversion body; (b) stringing the solar cells by providing at least one conductive ribbon and bonding (e.g., soldering) one end of each of the conductive ribbons over one of the conductive bus bar of one solar cell and the other end to the back electrode of an adjacent solar cell; (c) positioning each of a plurality of reflective strips over a front surface of each conductive ribbon, wherein the reflective strips have an average total reflectance of at least about 20% and a ratio of average diffuse reflectance to average total reflectance of at least about 0.2 (both determined at wavelengths of 300 to 1500 nm); (d) forming a pre-lamination structure wherein the structure from step (c) is sandwiched between a front encapsulant sheet and a back encapsulant sheet, which is further sandwiched between a frontsheet and a backsheet; (e) laminating the pre-lamination structure from step (d) under heat and optionally pressure and/or vacuum. In an alternative lamination process, during step (c) the reflective strips are applied over the conductive ribbons by first obtaining a solution containing the appropriate polymeric material and the optional additives, and then spray coating and drying the solution over the conductive ribbons. In one embodiment, the step (e) of the lamination process, the pre-lamination structure is laminated using a ICOLAM 10/08 laminator (purchased from Meier Solar solutions GmbH, Bocholt, Germany) at about 135° C. to about 150° C. and about 1 atm for about 10 to about 25 minutes.

### EXAMPLES

### Comparative Example CE1

In this example, eight (8) solar cell laminates were prepared using 8 monocrystalline silicone solar cells (125×125×0.2 mm, purchased from JASolar, China, under the trade name of Mono 5″(R150)125SOR2) having front and rear electrodes. In forming each of the 8 solar cell laminates, two conductive ribbons (2 mm wide and made of tinned copper strips) were soldered on the front surface of the solar cell on the two conductive bus bars of the solar cell front electrode, while on the back surface of the solar cell, another two conductive ribbons were soldered on the back electrode of the solar cell. The two front side conductive ribbons were connected by a first collecting wire, which had one end extending outside the final laminate, and the two back side conductive ribbons were connected by a second collecting wire, which also had one end extending outside the final laminate. The maximum power outputs of the unencapsulated solar cells as so prepared were measured using a Spi-Sun Simulator 3500SLP from Spire Corporation, Bedford, Mass., U.S.A. The results are shown in Table 1.

A pre-lamination structure was formed by sandwiching the monocrystalline solar cell as described immediately above between two 0.5 mm think ethylene-vinyl acetate (EVA) sheets, which was further sandwiched between a 3.2 mm thick glass sheet (on the front side) and a Tedlar® PVF/PET/Tedlar® PVF (“TPT”) backsheet (on the back side). (The TPT backsheet was an Icovolta® 2442 sheet purchased from Isovolt AG, Austria). Eight (8) encapsulated solar cell laminates were then obtained by laminating each of the 8 pre-lamination structures using a ICOLAM 10/08 laminator purchased from Meier Solar solutions GmbH, Bocholt, Germany for 15 minutes at 145° C. and 1 atm. Again, using a Spi-Sun Simulator 3500SLP from Spire Corporation, Bedford, Mass., U.S.A, the maximum power output of each of the 8 post lamination solar cell laminates were measured three times and averaged as shown in Table 1. The results demonstrate that the maximum power output of the solar cell laminates had an average increase of 8.46% over that of the unencapsulated solar cells.

### Example E1

Eight (8) solar cell laminates were prepared using 8 monocrystalline wafers, as described in CE1, wherein each of the 8 laminates had a similar structure as the laminates prepared in CE1, except that two reflective strips (15 μm thick, 2 mm wide) were bonded over the front (top) surface of the two front side conductive ribbons by Pressure Sensitive Adhesive 9930 purchased from Dongfeng Chemical co., Ltd. Jiangsu, China.

The reflective strips were made of Tedlar® PV2111 PVF films and had an average total reflectance of 71% and a ratio of average diffuse reflectance to average total reflectance of 0.98 (both determined at wavelength of 300 nm to 1500 nm). The average total reflectance and average diffuse reflectance of the reflective strips were determined using Lambda 950 UV/VIS/NIR spectrometer with a 150 mm integrating sphere attachment, both available from PerkinElmer, Wellesley, Mass., USA. The output was a percent total reflectance or percent diffuse reflectance at each wavelength and the spectral range measured was 300 nm to 1500 nm in 5 nm intervals. The reflectance standard was a calibrated SPECTRALON® standard purchased from LabSphere, North Sutton, N.H., USA and photomultiplier detection was used.

The maximum power outputs of the solar cells prior to the lamination process were measured as described in CE1 and are recorded in Table 2. The power outputs of the solar cell laminates after the lamination process were measured as described in CE1 and are tabulated in Table 2. The results demonstrated that, with the addition of the reflective strip, the maximum power output of the solar cell laminates has an average of 9.40% increase over that of the unencapsulated solar cells prior to lamination, which is an improvement over CE1 (i.e., solar cell laminates without the reflective strips).

### Example E2

Eight (8) solar cell laminates were prepared using 8 monocrystalline wafers as described in CE1, wherein each of the 8 laminates had a similar structure as the laminates prepared in CE1, except that two reflective strips (15 μm thick, 2 mm wide) were bonded over the front (top) surface of the two front side conductive ribbons by Pressure Sensitive Adhesive 9930 purchased from Dongfeng Chemical co., Ltd. Jiangsu, China.

The reflective strips were made of Melinex®238 polyester films obtained from DuPont Teijin Films Corporation, Japan, and had an average total reflectance of 26% and a ratio of average diffuse reflectance to average total reflectance of 0.82 (both determined at wavelength of 300 nm to 1500 nm).

The maximum power outputs of the unencapsulated solar cells prior to the lamination process were measured as described in CE1 and are recorded in Table 3. The power outputs of the solar cell laminates after the lamination process were measured as described in CE1 and are tabulated in Table 3. The results demonstrated that, with the addition of the reflective strip, the maximum power output of the solar cell laminates has an average of 9.35% increase over that of the unencapsulated solar cells prior to lamination, which is an improvement over CE1.

### Example E3

Eight (8) solar cell laminates were prepared using 8 monocrystalline wafers as described in CE1, wherein each of the 8 laminates had a similar structure as the laminates prepared in CE1, except that two reflective strips (15 μm thick, 2 mm wide) were bonded over the front (top) surface of the two front side conductive ribbons by Pressure Sensitive Adhesive 9930 purchased from Dongfeng Chemical co., Ltd. Jiangsu, China.

The reflective strips were made of Melinex®6429 polyester films obtained from DuPont Teijin Films Corporation, Japan, and had an average total reflectance of 85% and a ratio of average diffuse reflectance to average total reflectance of 0.95 (both determined at wavelength of 300 nm to 1500 nm).

The maximum power outputs of the solar cells prior to the lamination process were measured as described in CE1 and are recorded in Table 4. The power outputs of the solar cell laminates after the lamination process were measured as described in CE1 and are tabulated in Table 4. The results demonstrated that, with the addition of the reflective strip, the maximum power output of the solar cell laminates has an average of 9.01% increase over that of the unencapsulated solar cells prior to lamination, which is an improvement over CE1.

TABLE 1
Max Power Output (W)

| | | Solar Cell Module | | | | |
|---|---|---|---|---|---|---|
| | | (Post Lamination) | | | | |
| | Solar Cell | 1^{st} | 2^{nd} | 3^{rd} | | Power |
| | (Prior to | meas- | meas- | meas- | | Output |
| Test | Lami- | ure- | ure- | ure- | | Increase Post |
| Sample | nation) | ment | ment | ment | Average | Lamination |
| 1 | 2.2358 | 2.4283 | 2.4301 | 2.4306 | 2.4297 | 8.7% |
| 2 | 2.2417 | 2.4289 | 2.4329 | 2.4357 | 2.4325 | 8.5% |
| 3 | 2.2343 | 2.4337 | 2.4304 | 2.4372 | 2.4338 | 8.9% |
| 4 | 2.2367 | 2.4212 | 2.4287 | 2.4306 | 2.4268 | 8.5% |
| 5 | 2.2326 | 2.4138 | 2.4084 | 2.4176 | 2.4133 | 8.1% |
| 6 | 2.2473 | 2.4381 | 2.4405 | 2.4444 | 2.441 | 8.6% |
| 7 | 2.2310 | 2.4123 | 2.4075 | 2.4147 | 2.4115 | 8.1% |
| 8 | 2.2430 | 2.4341 | 2.4286 | 2.4278 | 2.4302 | 8.3% |
| Average | — | — | — | — | — | 8.46% |

TABLE 2
Max Power Output (W)

| | | Solar Cell Module | | | | |
|---|---|---|---|---|---|---|
| | | (Post Lamination) | | | | |
| | Solar Cell | 1^{st} | 2^{nd} | 3^{rd} | | Power |
| | (Prior to | meas- | meas- | meas- | | Output |
| Test | Lami- | ure- | ure- | ure- | | Increase Post |
| Sample | nation) | ment | ment | ment | Average | Lamination |
| 1 | 2.2429 | 2.4481 | 2.4546 | 2.4533 | 2.4520 | 9.3% |
| 2 | 2.2276 | 2.4294 | 2.4348 | 2.4381 | 2.4341 | 9.3% |
| 3 | 2.2466 | 2.4485 | 2.4518 | 2.4519 | 2.4507 | 9.1% |
| 4 | 2.2459 | 2.4681 | 2.4696 | 2.4572 | 2.4650 | 9.8% |
| 5 | 2.2311 | 2.4483 | 2.4494 | 2.4494 | 2.4490 | 9.8% |
| 6 | 2.2169 | 2.4299 | 2.4265 | 2.4316 | 2.4293 | 9.6% |
| 7 | 2.2354 | 2.4400 | 2.4425 | 2.4444 | 2.4423 | 9.3% |
| 8 | 2.2398 | 2.4394 | 2.4401 | 2.4437 | 2.4411 | 9.0% |
| Average | — | — | — | — | — | 9.40% |

TABLE 3
Max Power Output (W)

| | | Solar Cell Module | | | | |
|---|---|---|---|---|---|---|
| | | (Post Lamination) | | | | |
| | Solar Cell | 1^{st} | 2^{nd} | 3^{rd} | | Power |
| | (Prior to | meas- | meas- | meas- | | Output |
| Test | Lami- | ure- | ure- | ure- | | Increase Post |
| Sample | nation) | ment | ment | ment | Average | Lamination |
| 1 | 2.2795 | 2.4895 | 2.4936 | 2.4953 | 2.4928 | 9.4% |
| 2 | 2.2917 | 2.4955 | 2.4986 | 2.5048 | 2.4996 | 9.1% |
| 3 | 2.2880 | 2.4914 | 2.5024 | 2.5028 | 2.4989 | 9.2% |
| 4 | 2.2831 | 2.5019 | 2.4984 | 2.5022 | 2.5008 | 9.5% |
| 5 | 2.2846 | 2.4965 | 2.5025 | 2.5047 | 2.5012 | 9.5% |
| 6 | 2.2886 | 2.4999 | 2.5059 | 2.5068 | 2.5042 | 9.4% |
| 7 | 2.2918 | 2.4936 | 2.5023 | 2.5039 | 2.4999 | 9.1% |
| 8 | 2.2892 | 2.5044 | 2.5108 | 2.5148 | 2.5100 | 9.6% |
| Average | — | — | — | — | — | 9.35% |

TABLE 4
Max Power Output (W)

| | | Solar Cell Module | | | | |
|---|---|---|---|---|---|---|
| | | (Post Lamination) | | | | |
| | Solar Cell | 1^{st} | 2^{nd} | 3^{rd} | | Power |
| | (Prior to | meas- | meas- | meas- | | Output |
| Test | Lami- | ure- | ure- | ure- | | Increase Post |
| Sample | nation) | ment | ment | ment | Average | Lamination |
| 1 | 2.2917 | 2.5050 | 2.5085 | 2.5115 | 2.5083 | 9.5% |
| 2 | 2.2898 | 2.4949 | 2.5025 | 2.4970 | 2.4981 | 9.1% |
| 3 | 2.2898 | 2.5001 | 2.4998 | 2.5006 | 2.5002 | 9.2% |
| 4 | 2.2858 | 2.4862 | 2.4915 | 2.4923 | 2.4900 | 8.9% |
| 5 | 2.2933 | 2.4887 | 2.4916 | 2.4971 | 2.4925 | 8.7% |
| 6 | 2.2868 | 2.4828 | 2.4853 | 2.4871 | 2.4851 | 8.7% |
| 7 | 2.2878 | 2.4831 | 2.4906 | 2.4930 | 2.4889 | 8.8% |
| 8 | 2.2848 | 2.4886 | 2.4938 | 2.4998 | 2.4941 | 9.2% |
| Average | — | — | — | — | — | 9.01% |

What is claimed is:

1. A solar cell module with a plurality of solar cells each comprising:
a photoelectric conversion body having a light receiving front surface;
one or more electrically conductive ribbons disposed over a portion of the front surface of said photoelectric conversion body, said electrically conductive ribbons having opposite first and second sides, the first side of the electrically conductive ribbons facing and being electrically connected to said photoelectric conversion body; and
one or more reflective strips disposed over the second side of said one or more electrically conductive ribbons, wherein each of the reflective strips has an average total reflectance of at least about 20% and a ratio of average diffuse reflectance to average total reflectance of at least about 0.2, where the average total reflectance and the average diffuse reflectance are measured at wavelengths from 300 to 1500 nm.

2. The solar cell module of claim 1 wherein each of the plurality of solar cells comprises two of said electrically conductive ribbons and a reflective strip over the second surface of each of said electrically conductive ribbons.

3. The solar cell module of claim 1, wherein each of the plurality of solar cells further comprises:
a front electrode on the light receiving front surface of the photoelectric conversion body, the front electrode comprising a plurality of substantially parallel electrically conductive fingers and one or more electrically conductive bus bars substantially perpendicular to and connected to the electrically conductive fingers, wherein each of said electrically conductive ribbons is aligned with and bonded to one of the electrically conductive bus bars; and
a back electrode printed over a back surface of the photoelectric conversion body that is opposite the front surface.

4. The solar cell module of claim 3, wherein each of the electrically conductive ribbons is soldered to one of the electrically conductive bus bars.

5. The solar cell module claim 1, wherein each of the reflective strips has an average total reflectance of at least about 50%, and a ratio of average diffuse reflectance to average total reflectance of at least about 0.5, where the average total reflectance and the average diffuse reflectance are measured at wavelengths from 300 to 1500 nm.

6. The solar cell module of claim 1, wherein each of the reflective strips comprises a polymer composition comprising at least one polymeric material selected from the group consisting of fluoropolymers, polyesters, polyolefins, ethylene vinyl acetates, polycarbonates, polyurethanes, silicones, epoxy resins, and combinations of two or more thereof.

7. The solar cell module of claim 6, wherein the polymer composition in each of the reflective strips further comprises at least one additive selected from the group consisting of titanium dioxide, silica, aluminum oxide, zinc oxide, magnesium oxide, calcium carbonate, aluminum silicate, calcium sulfate, silicon carbide, barium carbonate, barium sulfate, and combinations of two or more thereof.

8. The solar cell module of claim 7, wherein the polymer composition in each of the reflective strips comprises a fluoropolymer and titanium oxide particles.

9. The solar cell module of claim 8, wherein the polymer composition in each of the reflective strips comprises polyvinyl fluoride and about 10-30 wt % of titanium oxide particles, based on the total weight of the polymer composition.

10. The solar cell module of claim 6, wherein the reflective strip has a first side facing the conductive ribbon over which the reflective strip is disposed and an opposite second side, and wherein each of the reflective strips further comprises a reflective coating on the second side of the reflective strip wherein the reflective coating comprises a material selected from the group consisting of titanium dioxide, silica, aluminum, silver, and a combination of two or more thereof.

11. The solar cell module of claim 3, wherein each of the electrically conductive ribbons has a width that is about 70-100% of that of the conductive bus bar the electrically conductive ribbon is bonded over.

12. The solar cell module of claim 11, wherein each of the electrically conductive ribbons has (i) a main portion that covers at least about 95% of the entire length of the conductive bus bar that the electrically conductive ribbon is bonded over and (ii) an extended portion that extends beyond the conductive bus bar that the electrically conductive ribbon is bonded over and that is bonded to the back electrode of an adjacent solar cell of the plurality of solar cells of the solar cell module.

13. The solar cell module of claim 12, wherein each of the reflective strips has a width that is at least 80% of the width of the conductive ribbon it is disposed over, and wherein each of the reflective strips covers at least 95% of the portion of each conductive ribbon that is aligned with and bonded to a bus bar.

14. The solar cell module of claim 1, wherein the plurality of solar cells are electrically connected to each other and are encapsulated between a front encapsulant sheet and a back encapsulant sheet.

15. The solar cell module of claim 14, wherein each of the front encapsulant sheet and the back encapsulant sheet independently comprises a polymeric material selected from the group consisting of ethylene vinyl acetates, ionomers, poly(vinyl butyral), polyurethanes, polyvinylchlorides, polyethylenes, polyolefins, ethylene acrylate ester copolymers, acid copolymers, silicones, epoxy resins, and combinations of two or more thereof.

16. The solar cell module of claim 14, wherein the encapsulated solar cells are further sandwiched between a transparent frontsheet and a backsheet.

17. The solar cell module of claim 16, wherein the transparent frontsheet is selected from the group consisting of glass sheets and plastic sheets and the backsheet is selected from the group consisting of glass sheets, plastic sheets, metal sheets, and ceramic plates, and wherein the plastic sheets comprise material selected from the group consisting of polycarbonates, acrylics, polyacrylates, cyclic polyolefins, ethylene norbornene polymers, polystyrenes, polyamides, polyesters, fluoropolymers, and combinations of two or more thereof.
